(19) United States
(12) Patent Application Publication
(10) Pub. No.: US 2004/0161946 A1
(43) Pub. Date: Aug. 19, 2004

(54) Method for fluorocarbon film depositing

(76) Inventors: Hsin-Yi Tsai, Hsinchu (TW); Ming Chung Liang, Hsinchu (TW)

Correspondence Address: Stout, Uxa, Buyan & Mullins, LLP, Suite 300, 4 Venture, Irvine, CA, 92618, US

(21) Appl. No.: 10/178,910

(22) Filed: Jun. 24, 2002

(51) Int. Cl. H01L 21/31

(52) U.S. Cl. 438/778

(57) ABSTRACT

A thin fluorocarbon layer is deposited onto the surface of a substrate through the application of a plasma enhanced chemical vapor deposition process, wherein the substrate is placed on a chuck within a reaction chamber and fluorocarbon gas is introduced into the reaction chamber under the influence of a first plasma source and a second plasma source. The fluorocarbon gas is a CₓF_{y} gas, wherein the ratio y/x is less than 2. The plasma source ionizes the fluorocarbon gas by applying RF plasma energy, and the second plasma source applies a self-bias to the substrate at an RF frequency. The ionized fluorocarbon is deposited onto and adheres to the substrate to form a thin film of fluorocarbon on the substrate.

### BACKGROUND OF THE INVENTION

1. Field of the Invention

The present invention relates generally to insulating structures for use on semiconductor substrates and, more particularly, to plasma enhanced chemical vapor deposition methods for forming thin dielectric layers on integrated circuits.

2. Description of Related Art

As integrated circuit devices are progressively miniaturized and packaged closer together, the number and density of interconnects commensurately increases. Smaller interline and interlevel separations of these interconnects (e.g., conductive lines and vias), coupled with reduced interconnect geometries, help to facilitate the greater interconnect densities.

Reduced interconnect separations and geometries, however, can undesirably augment capacitances (C) and resistances (R), respectively, of the interconnect structures. These increased electrical properties can introduce, for example, cross talk noise and propagation delays between interlevel and intralevel conductive interconnects. The reduction or elimination of adverse capacitive couplings, for instance, could advantageously lead to enhanced device speed and reduced power consumption.

In the context of integrated circuits it is known that capacitance can be attenuated by employing lower dielectric constant insulating materials. Thus, the trend to decrease device geometries emphasizes the importance of depositing effective insulation layers between conducting paths (interconnects) for achieving proper device performance.

A common material that is conventionally used for the formation of insulative layers in the semiconductor industry is silicon dioxide (SiO₂), which has a dielectric constant of approximately four. Having one of the lowest dielectric constants of known inorganic materials, silicon dioxide has long been used in integrated circuits as a primary insulating material. The dielectric constant of a silicon dioxide film may increase to about ten, however, upon exposure thereof to moisture.

The addition of relatively small amounts of fluorine into silicon dioxide films has been found in the prior art to actually lower the dielectric constant down into the low to mid three range. Further reduction of the dielectric constant, however, will typically require more advanced and committed uses of organic materials. On the topic of organic materials, fluorocarbon-based polymers have been recognized in the prior art as potentially attractive low-dielectric constant materials.

Plasma reactors can be used to deposit dielectric films onto the surfaces of integrated circuits. These plasma reactors ionize one or more gases with energy, which is typically in the form of radio frequency (RF) signals, in a plasma chamber. Energy from a RF plasma source may be inductively introduced into a plasma chamber, or the energy may be introduced via an electrode. The ionized gases adhere to the surfaces of the integrated circuits within the plasma reactors, thereby forming dielectric films on the integrated circuits. These techniques are generally referred to as plasma enhanced chemical vapor deposition (CVD) or (PECVD) procedures. As an example, a fluorocarbon film may be produced by ionizing a fluorocarbon gas in a plasma reactor and then depositing the ionized gas onto an integrated circuit.

However, plasma enhanced CVD processes can be relatively difficult to control. In particular, the formation of a suitably thin and/or optimally distributed layer of fluorocarbon onto a semiconductor substrate, with for example a relatively low dielectric value, can be difficult. For instance, conventional depositions of a fluorocarbon film onto a substrate can entail multiple processes and can result in relatively poor control of the thickness of the deposited film over different portions of the substrate. When the substrate comprises features, such as photoresist features or other patterned blocks, the relatively poor control can be particularly prevalent.

In addition, conventional plasma enhanced CVD reactors may require relatively high temperatures for the deposition of a fluorocarbon film onto the surface of a substrate. In cases where the substrate comprises organic materials, such as substrates having photoresist features, the high temperatures may undesirably damage the organic material.

Photoresist features, in addition to being temperature sensitive, can also affect overall circuit densities based upon the resolution of the photolithographic process used to form the features. Integrated circuits are generally categorized by critical dimensions (i.e., sizes) of electronic devices, and/or densities of electronic devices per unit area. Making integrated circuits denser necessarily entails reducing critical dimensions between features. Limits of lithographic processes used to form features can determine critical dimensions of electronic devices, as well as minimum spacing distances between the features.

There is a need in the prior art for methods of reduced complexity which are suitable for depositing thin films of fluorocarbon. A need also exists for methods of depositing thin films of fluorocarbon that may exhibit improved, controllable distributions of thicknesses over surface features of a substrate. There is also a need for a method or an improved method of depositing thin fluorocarbon films onto the surfaces of organic materials at sufficiently low temperatures to attenuate or avoid damage to the organic materials. Furthermore, in order to increase the density of electronic devices per unit area (i.e., achieve higher levels of device integration), an ongoing need exists to reduce spacing distances between adjacent features of integrated circuits.

### SUMMARY OF THE INVENTION

The present invention seeks to meet these needs by providing, in accordance with one aspect of the present invention, methods of depositing improved dielectric films onto semiconductor circuit constructions. The various embodiments of the present invention may include or address one or more of the following objectives. One objective is to provide a method for improving the control over a plasma enhanced CVD process. Another object is to provide a method of or an improved method of depositing a thin, low-dielectric fluorocarbon film onto the surface of an integrated circuit, wherein the film is formed in one time and one process by a CVD process. Another object is to provide a method for depositing a fluorocarbon film having an improved distribution of thicknesses over features of a substrate, compared to similar structures of the prior art. Still another objective of the present invention is to provide a method for depositing a fluorocarbon film onto the surface of a substrate at a relatively low temperature to avoid damage to certain components or compositions, such as organic material layers, of the substrate. Yet another objective is to form a polymer layer on features of a substrate to reduce the critical dimension of the openings between the features. The features can comprise photoresist features.

To achieve these and other advantages and in accordance with a purpose of the present invention, as embodied and broadly described herein, the invention provides a method for depositing a fluorocarbon film onto a substrate, including a step of providing a reacting gas which comprises a CₓF_{y} gas, wherein the ratio y/x is less than 2; and providing a first plasma source and a second plasma source to deposit a fluorocarbon film on the surface with the CₓF_{y} gas. The reacting gas may consist essentially of the CₓF_{y} gas. In accordance with one aspect of the present invention the reacting gas comprises C₅F₈, and in accordance with another aspect of the invention the reacting gas comprises C₄F₆. The first plasma source may comprise a radio frequency (RF) plasma source, and in accordance with another aspect the second plasma source may comprise a radio frequency plasma source. The first plasma source ionizes the reacting gas, and the second plasma source provides the substrate with a self-bias for improved control of the deposition process.

In one implementation of the present invention, a method of depositing a fluorocarbon film onto a surface of a substrate comprises the steps of placing a substrate into a reaction chamber and introducing a reaction gas into the reaction chamber, wherein the reaction gas consists essentially of a CₓF_{y} gas with the ratio y/x being less than 2. The method further comprises a step of ionizing the reaction gas with a first plasma source, a step of biasing the substrate with a second plasma source, and a step of depositing a fluorocarbon film onto the substrate with the CₓF_{y} gas. In exemplary embodiments, the reaction gas may comprise either C₅F₈ or C₄F₆. In accordance with another embodiment, the reaction gas consists essentially of at least one of C₅F₈ or C₄F₆. The first plasma source may comprise a radio frequency plasma source for ionizing the reaction gas, and in accordance with another aspect of the invention the second plasma source may comprise a radio frequency plasma source for self-biasing the substrate.

In accordance with another aspect of the present invention, a method of depositing a fluorocarbon film onto a substrate comprises the steps of pumping a CₓF_{y} gas into a plasma chamber, wherein the ratio y/x is less than 2. The method further comprises the steps of ionizing the CₓF_{y} gas with a first plasma source, and biasing a substrate within the plasma chamber with a second plasma source. A fluorocarbon film is deposited onto a surface of the substrate with the CₓF_{y} gas. In certain embodiments, the fluorocarbon film can be comprised essentially of elements from the CₓF_{y} gas, or may consist only of elements from the CₓF_{y} gas. The CₓF_{y} gas can comprise C₄F₆ and/or can comprise C₅F₈, and the first and second plasma sources can comprise radio frequency plasma sources.

According to yet another aspect of the present invention, a thin fluorocarbon layer is deposited onto the surface of a substrate through the application of a plasma enhanced chemical vapor deposition process in which a substrate is placed on a chuck within a reaction chamber. Fluorocarbon gas is introduced into the reaction chamber under the influence of a first plasma source and a second plasma source. The fluorocarbon gas comprises a CₓF_{y} gas, wherein the ratio y/x is less than 2. The first plasma source ionizes the fluorocarbon gas by applying RF plasma energy, and the second plasma source applies a self-bias to the substrate at an RF frequency. The ionized fluorocarbons are deposited onto and adhere to the substrate, thereby forming a thin film of fluorocarbon onto the substrate.

In each of the foregoing aspects, the present invention introduces a fluorocarbon gas, expressed by CₓF_{y} where the ratio y/x is less than 2, into a reaction chamber under the influence of a first plasma source and a second plasma source, for the plasma enhanced chemical vapor deposition of a fluorocarbon film onto a substrate with the fluorocarbon gas.

Any feature or combination of features described herein are included within the scope of the present invention provided that the features included in any such combination are not mutually inconsistent as will be apparent from the context, this specification, and the knowledge of one of ordinary skill in the art.

Additional advantages and aspects of the present invention are apparent in the following detailed description and claims. It is to be understood that both the foregoing general description and the following detailed description are exemplary, and are intended to provide further explanation of the invention as claimed.

### BRIEF DESCRIPTION OF THE DRAWINGS

FIG. 1 is an enlarged, not-to-scale cross sectional view of a dual plasma source apparatus for depositing thin films onto substrates in accordance with the present invention; and

FIG. 2 is a flowchart in accordance with a process of the present invention for depositing a thin film of fluorocarbon on a substrate.

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same reference numbers are used in the drawings and the description to refer to the same or like parts. It should be noted that the drawings are in greatly simplified form and are not to precise scale. In the following description, numerous specific details are set forth illustrating Applicants' best mode for practicing the invention and enabling one of ordinary skill in the art to make and use the invention. It will be understood, however, to one skilled in the art that the present invention may be practiced in certain applications without these specific details. Thus, the illustrated embodiments set forth herein are presented by way of example and not by way of limitation

The intent of the following detailed description is to cover all modifications, alternatives, and equivalents as may fall within the spirit and scope of the invention as defined by the appended claims. It is to be understood and appreciated that the process steps and structures described herein do not cover a complete process flow for the deposition of, for example, a fluorocarbon film onto an integrated circuit substrate using first and second plasma sources. The present invention can be practiced in conjunction with various plasma enhanced chemical vapor deposition techniques and integrated circuit fabrication methods that are used in the art, and only so much of the commonly practiced process steps are included herein as are necessary to provide an understanding of the present invention. In certain instances, well-known machines and process steps have not been illustrated or described in particular detail in order to avoid unnecessarily obscuring the present invention.

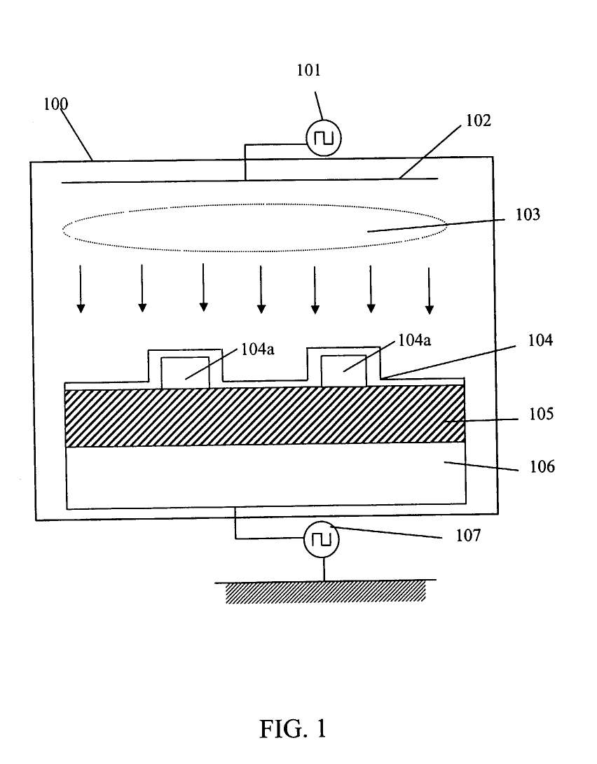

Referring more particularly to the drawings, an exemplary apparatus for practicing the process of the present invention on a substrate to thereby deposit a thin dielectric material thereon is shown in FIG. 1. The process of the present invention can be practiced in a controlled environment, which can be created within a reaction chamber 100. The reaction chamber 100 can be constructed from, for example, stainless steel, and is preferably gas-tight.

In the illustrated embodiment, the reaction chamber 100 comprises a dual plasma etcher, and CVD is utilized to directly, in one time and one process, form a fluorocarbon film 104 over features 104a and also optionally over the substrate 103.

The reaction chamber 100 comprises structure, such as a vacuum pump and pressure controller (not shown), that is constructed to generate a desired pressure within the chamber 100. As presently embodied, the walls of the chamber and surfaces of two electrodes 102 and 106 are coated with a film which is compatible with the plasma enhanced CVD process to be performed.

The reaction chamber 100 can further comprise a configuration, such as tanks and valves (not shown), that is adapted to efficiently pump one or more gases 103 at controlled rates into the reaction chamber 100. The gases 103 can be introduced into the reaction chamber 100 through one or more orifice structures (not shown), such as ring-shaped distributors or shower head assemblies or any other suitable structures for introducing gases in a distributed fashion into the reaction chamber 100 during the performance of a plasma enhanced CVD procedure. In a one embodiment, the location of each orifice structure is in close proximity to the electrode 102. Each orifice structure can be disposed generally between the electrode 102 and a substrate 105, so that gases 103 entering into the reaction chamber 100 encounter RF plasma energy from the first plasma source 101 and are ionized between the electrode 102 and the chuck/electrode 106. The reaction chamber 100 can additionally comprise an exhaust port (not shown) for removing spent plasma and gases from the reaction chamber 100.

In accordance with the illustrated embodiment, a first plasma source 101 is used to generate energy, known as plasma energy, sufficient to ionize one or more gases 103 within the reaction chamber 100. In accordance with methods of the present invention, the first plasma source 101 can be operated (e.g., its power varied) to control the ion concentration of the ionized gases 103. The first plasma source 101 may be electrically coupled to an electrode 102, comprising for example a conductive material such as aluminum, as shown in FIG. 1.

In an alternative embodiment, the plasma energy may be inductively transmitted to the gases 103 within the reaction chamber 100. Inductively transmitting energy into the reaction chamber 100 may be accomplished by wrapping conductive coils around the reaction chamber 100 and then applying RF energy to the coils. A plasma region is thus generated inside the reaction chamber 100 even though the coils are on the outside.

As presently preferred, the plasma energy comprises radio frequency (RF) plasma energy. In particular, the first plasma source 101 can comprise a radio frequency (RF) modulator for generating high-frequency RF signals, which are transmitted from the first electrode 102 within the reaction chamber 100 in close proximity to the gases 103. In the illustrated embodiment, the RF signals are transmitted at a frequency of 13.56 MHz, which frequency is an industry standard for plasma energy use in plasma enhanced CVD champers. In modified embodiments, the RF plasma energy may be supplied at any other frequency that, when exposed to the gases 103 under suitable conditions, will ionize the gases 103 generating polymer radicals which are deposited on the substrate 105. The RF plasma energy can be applied at a power level of 0 to 3000W

The substrate 105, which preferably comprises a semiconductor wafer having integrated circuits disposed thereon, is positioned on the chuck/electrode 106 within the reaction chamber 100 as an initial step to the deposition process of the present invention. The chuck/electrode 106 holds and/or supports the substrate 105 and may be used as part of a thermal-control system (not shown) to control the temperature of the substrate 105 during the deposition process. The thermal-control system may comprise, for example, a probe or thermostat disposed in, on, or in close proximity to the chuck/electrode 106 for regulating a temperature of the substrate 105. In one embodiment, a heating element and a cooling element are both disposed within the chuck/electrode 106 and remotely controlled by a temperature control. The heating element may comprise a resistive heating element, and the cooling element may comprise a cooling channel and/or surface of the chuck/electrode 106 for accommodating or contacting a cooling fluid such as water or liquid Helium.

As presently embodied, the temperature control can operate to keep the substrate 105 within a temperature range of about 10 to about 80 degree Celsius, and in the illustrated embodiment at a temperature of about 20 degree Celsius, for example, to prevent damage to one or more organic components on the substrate 105 The substrate 105 as shown in FIG. 1 may be at an intermediate processing step during its manufacturing process and, thus, may have a top-most surface layer of, for example, a photoresist layer, a bottom or barrier anti-reflective coating (BARC) layer, a dielectric layer, an insulating layer, a conductive layer, or a combination thereof. In the illustrated embodiment, the top-most surface layer comprises surface features, such as photoresist blocks. When the exposed substrate 105 surface is not planar, as shown in the figure, the deposition method of the present invention may advantageously be able to facilitate a controlled distribution of thicknesses over surface features of the substrate and over features disposed on the substrate

A second plasma source 107 can be used to control the deposition process by, for example, self-biasing the substrate 105. The second plasma source 107 is preferably electrically (e.g., capacitively) connected to the chuck/electrode 106, and the chuck/electrode 106 in turn contacts the substrate 107 during the deposition operation to thereby self-bias the substrate 105. In particular, the second plasma source 107 preferably comprises a radio frequency (RF) modulator for generating high-frequency RF signals, which are transmitted to and radiate from the chuck/electrode 106. The RF signals are preferably transmitted at a frequency of 13.56 MHz, but in modified embodiments the RF plasma energy may be supplied at other frequencies The RF plasma energy can be applied at a power level of 800 to 1500W

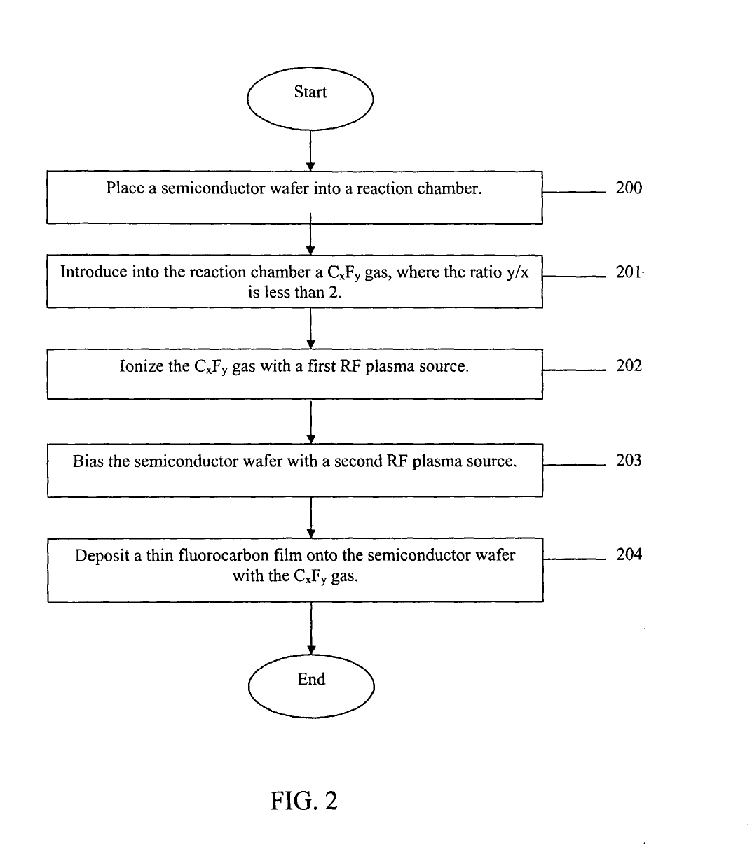

A preferred process will now be discussed with reference to FIGS. 1 and 2. In operation, the substrate 105, which preferably is a semiconductor wafer having integrated circuit formations disposed thereon, is placed on the electrode/chuck 106 within the reaction chamber 100 at Step 200. The reaction chamber 100 is sealed and then pressurized, using for example a vacuum pump in combination with one or more reacting gases, to an ambient pressure of about 3 mTorr to about 200 mTorr, and preferably about 7 mTorr to about 30 mTorr.

While maintaining the desired pressure and temperature, one or more reacting gases 103 are introduced into the reaction chamber 100 at a controlled ratio and flow rate, as shown at Step 201. In modified embodiments, the desired pressure may be set either before, during (iteratively) or after the flow rates of the gases are set. In a preferred method, the reacting gas comprises fluorocarbon which is pumped into the reaction chamber at a flow rate ranging, for example, from about 100 to 800 sccm, per cubic meter, and in the illustrated embodiment at a flow rate of 500 sccm, per cubic meter.

The fluorocarbon gas is defined herein as a CₓF_{y} gas where y/x is less than 2, such as C₄F₆ or C₅F₈. In accordance with one aspect of the present invention, a higher ratio of C in relation to F may allow for a better or optimal deposition of the fluorocarbon film 104 onto the surface of the substrate 105. The gases 103 are introduced into the reaction chamber 100 at a flow rate so that, under sufficiently applied energy, a fluorine and carbon gas plasma will be formed in the reaction chamber 100 as discussed below with reference to Step 202. The reacting gas may further comprise CO, Ar, N₂ and/or O₂. In one embodiment the reacting gas for forming the fluorocarbon film comprises all of the following: CO, Ar, N₂ and O₂.

In accordance with one aspect of the present invention, the use of CO and Ar in a certain proportion can facilitate control of the profile of the fluorocarbon film over the features. For example, the range of CO can be controlled from 0 to about 150 sccm, and in a preferred embodiment from about 85 to about 115 sccm, and more preferably at about 100 sccm; and the range of Ar can be controlled from 0 to about 300 sccm, and more preferably from about 150 to about 300 sccm.

The amount of gas 103 delivered to the reaction chamber 100 may be adjusted as needed to control the deposition process. For example, the flow rate of the gas 103 during the plasma enhanced CVD process can be the rate required to maintain the ambient pressure within the reaction chamber 100 at a desired range. In certain embodiments of the present invention, the deposition rate and process can be selectively controlled by altering the flow rates of the gases, the composition of the gases 103, the pressure within reaction chamber 100, the energy outputs of the first plasma source 101 and the second plasma source 107, and the substrate 105 temperature, so long as plasma enhanced CVD is maintained under the influence of the first plasma source 101 and the second plasma source 107 in accordance with the present invention. In modified embodiments, other carbon containing gases and/or fluorine containing gases may be supplied alone or in combination with the above-described gases.

In Step 202, the first plasma source 101 is used to ionize the gases 103 by applying RF plasma energy at a frequency of about 13.56 MHz and at an energy level of about 1300 Watts to the electrode 102 in proximity to the gases 103. The RF plasma energy may alternatively be inductively coupled into the reaction chamber 100 to ionize the gases 103. The plasma energy in the reaction chamber 100 ionizes the introduced gases 103, generating, for example, radical species that may comprise monomer, oligomer and/or polymer radicals which are deposited onto the surface of the substrate 105. For example, a CₓF_{y} gas introduced into the reaction chamber 100 may be ionized into radicals including fluorocarbon radicals (e.g., CF or CF₂) and fluorine (F or F₂) atoms/molecules. The ionized gas 103, or plasma, is deposited onto and adheres to the surface of the substrate 105 thereby forming the thin fluorocarbon film 104.

With reference to Step 203, additional control over the process is achieved by applying power to the second plasma source 107 at a frequency of about 13.56 MHz. RF plasma energy is applied from the second plasma source 107 to the chuck/electrode 106 at an energy range of from about 0 Watts to about 1100 Watts and, preferably, at an energy level of about 200 Watts to thereby apply a dc voltage self-bias to the substrate 105, as measured by, for example, a suitably configured voltage meter. In the illustrated embodiment, the substrate 105 may be self-biased to a potential of about 0 to 350V, and even more preferably, to a value of about 200V

The ionized gas plasma 103 is deposited onto and adheres to the substrate 105, thereby forming the thin film of material 104 on the surface of the substrate 105 as shown at Step 204. Ionized fluorocarbon gas will form the fluorocarbon film 104 on the surface of the substrate 105 in accordance with the inventive processes set forth herein, wherein the thin fluorocarbon film 104 thus formed can have a better distribution of thicknesses over surface features of a substrate, compared to prior art methods. The inventive process may also be practiced on substrates having organic material, since the process may be performed at lower temperatures, relative to temperatures used in connection with prior art deposition methods.

Regarding formation of the fluorocarbon film 104, an etcher can be utilized in combination with a recipe for controlling the deposition/etching ratio in reaction so as to form the fluorocarbon film 104 on the side walls and/or top surfaces of the photoresist layer 20. The thickness of the fluorocarbon film 104 can be controlled at each portion of the surface including the surfaces of the features 104a, which can be photoresist blocks, and of the substrate. By tuning the recipe of reaction, the surface between two features 104a can be disposed with a fluorocarbon layer in a thickness smaller than that on the top surfaces of the features, or disposed with no fluorocarbon, or even be slightly etched away. The thicknesses of the film on the various surfaces, in accordance with the invention, depends upon the gases used and the other recipe such as power. The thickness may further be spatially controlled, in other embodiments, based upon one or more of the following: the flow rates of the gases, the composition of the gases, the pressure within reaction chamber, the relative energy outputs of the first plasma source and/or the second plasma source, and the substrate 105 temperature. The fluorocarbon film 104 can thus be formed, with a controlled spatial distribution of thicknesses, in a single CVD process without the need of other processes.

The fluorocarbon film 104 can be selectively formed on surfaces of the features 104a using, for example, in whole or in part, the methods and apparatus disclosed in co-pending U.S. application Ser. No. 09/978,546, filed Oct. 18, 2001, and co-pending U.S. application Ser. No. ______, filed Jun. 24, 2002 and entitled Method of Forming a Fluorocarbon Polymer Film on a Substrate Using a Passivation Layer, the contents of both which are incorporated herein by reference. The polymer layer, i.e., the fluorocarbon layer, can be controlled to cover the top wall and the side wall of the features (e.g., the photoresist blocks) in different thicknesses. In a case wherin the deposition thickness on the top wall is lager than that on the side wall, the polymer layer can be used as a protection layer to prevent the profile of the photoresist blocks from being damaged during etching. In a case wherein the deposition thickness on the sidewall is relatively large, the polymer can be used to attenuate the critical dimension of the opening between photoresist features. That is, the thickness on the sidewall can be larger than that on the surface of the underlayer (e.g., substrate).

Once a desired film thickness has been achieved in accordance with Step 204, the process may be terminated and the substrate 105 removed, using conventional means such as an automated handler. The fluorocarbon film 104 may be tested for proper deposition characteristics, including dielectric constant, thicknesses at one or more different locations, and/or uniformity of distribution at the one or more locations. In the preceding paragraph it was mentioned that the thickness of the fluorocarbon film 104 can be controlled at each portion of the surface including the surfaces of the features 104a. Thus, in accordance with one aspect of the invention, the thickness of the fluorocarbon film 104 can be controlled on the sidewalls of the features to thereby vary the opening between features. Thus, to the extent that the features 104a comprises photoresist features having a spacing which is as small as a photolithographic process will allow, for example, adding the fluorocarbon film 104 onto the sidewalls of the features will further decrease the critical dimension of the spacing (i.e., opening) between the features. In this embodiment, wherein the thickness of the fluorocarbon film on the sidewalls of the features is varied to control a spacing between the features, it can be advantageous to further control the conditions of the process so that the fluorocarbon film is not deposited on the substrate between the features.

In view of the foregoing, it will be understood by those skilled in the art that the methods of the present invention can facilitate formation of dielectric layers having improved characteristics in relation to those of the prior art. The above-described embodiments have been provided by way of example, and the present invention is not limited to these examples. Multiple variations and modification to the disclosed embodiments will occur, to the extent not mutually exclusive, to those skilled in the art upon consideration of the foregoing description. Such variations and modifications, however, fall well within the scope of the present invention as set forth in the following claims.

We claim:

1. A method for depositing a fluorocarbon film on a substrate having a surface, the method comprising the step of:
providing a reacting gas, the reacting gas comprising a CₓF_{y} gas, wherein the ratio y/x is less than 2; and
providing at least one plasma source to deposit a fluorocarbon film on the surface with the CₓF_{y} gas.

2. The method of claim 1, wherein the at least one plasma source comprises a first plasma source and a second plasma source.

3. The method of claim 2, wherein the reacting gas comprises at least one of C₅F₈ and C₄F₆.

4. The method of claim 2, wherein:
the reacting gas further comprises CO, Ar, N₂ and O₂; and
the CO is provided at a rate of 0 to about 150 sccm and the Ar is provided at a flow rate of 0 to about 300 sccm.

5. The method of claim 4, wherein the CO is provided at a rate of about 85 to about 115 sccm and the Ar is provided at a flow rate of about 150 to about 300 sccm.

6. The method of claim 4, wherein:
the second plasma source comprises a radio frequency plasma source; and
the second plasma source is used to provide the substrate with a self-bias.

7. A method of depositing a fluorocarbon film onto a surface of a substrate comprising the steps of:
a) placing a substrate into a reaction chamber;
b) introducing a reaction gas into the reaction chamber, the reacting gas comprising a CₓF_{y} gas, wherein the ratio y/x is less than 2;
c) depositing a fluorocarbon film onto the substrate with the CₓF_{y} gas.

8. The method of claim 7, wherein the depositing is preceded both by a step of ionizing the reaction gas with a first plasma source and by a step biasing the substrate with a second plasma source.

9. The method of claim 8, wherein the reaction gas comprises at least one of C₅F₈ and C₄F₆.

10. The method of claim 8, wherein:
the reacting gas further comprises CO, Ar, N₂ and O₂; and
the CO is provided at a rate of 0 to about 150 sccm and the Ar is provided at a flow rate of 0 to about 300 sccm.

11. A method of depositing a fluorocarbon film on a substrate having a surface, the method comprising the steps of:
a) pumping a CₓF_{y} gas into a plasma chamber, wherein the ratio y/x is less than 2;
b) applying at least one plasma source; and
c) depositing a fluorocarbon film onto the surface of the substrate with the CₓF_{y} gas.

12. The method of claim 11, wherein the CₓF_{y} gas comprises at least one of C₅F₈ and C₄F₆.

13. The method of claim 11, wherein:
the reacting gas further comprises CO, Ar, N₂ and O₂; and
the CO is provided at a rate of 0 to about 150 sccm and the Ar is provided at a flow rate of 0 to about 300 sccm.

14. The method of claim 11, wherein the CO is provided at a rate of about 85 to about 115 sccm and the Ar is provided at a flow rate of about 150 to about 300 sccm.

15. The method of claim 13, wherein the step of applying at least one plasma source comprises ionizing the CₓF_{y} gas with a first plasma source and biasing the substrate with a second plasma source.

16. The method as set forth in any of claims 2, 8, and 15, wherein:
the substrate comprises blocks; and
the fluorocarbon film is deposited on the blocks but not on portions of the substrate between the blocks.

17. The method as set forth in claim 16, wherein the blocks comprise photoresist.

18. The method as set forth in any of claims 2, 8, and 15, wherein:
the substrate comprises blocks; and
the fluorocarbon film is deposited on the blocks, so that a thickness of the fluorocarbon film on top surfaces of the blocks is less than a thickness of the fluorocarbon film on sidewalls of the blocks.

19. The method as set forth in claim 18, wherein the blocks comprise photoresist.

20. The method as set forth in claim 18, wherein the fluorocarbon film is not deposited on portions of the substrate between the blocks.

21. The method as set forth in claim 20, wherein the blocks comprise photoresist.

22. The method of claim 1, wherein the at least one plasma source is a single plasma source, which is used to provide the substrate with a self-bias.
